(19) United States
(12) Patent Application Publication
(10) Pub. No.: US 2005/0007747 A1
(43) Pub. Date: Jan. 13, 2005

(54) Metal electronics device enclosure

(76) Inventor: Michael Axelrod, Roswell, GA (US)

Correspondence Address: ARRIS INTERNATIONAL, INC, 3871 LAKEFIELD DRIVE, SUWANEE, GA, 30024, US

(21) Appl. No.: 10/889,552

(22) Filed: Jul. 12, 2004

Related U.S. Application Data
(60) Provisional application No. 60/486,504, filed on Jul. 11, 2003.

(51) Int. Cl. H05K 5/00; H05K 5/04; H05K 5/06

(52) U.S. Cl. 361/752

(57) ABSTRACT

An electronics housing made of metallic members is assembled when a attachment slot of a first member receives attachment cam-tabs of a second member. The hook-like tabs are shaped so as to produce a cam effect as the tabs slide under a portion of the first member such that the further the two members are slid together, the more tightly the two members are secured together. The depth and size of the hook is specified to bears against a circuit board within the housing such that the board is securely located in the housing. In addition, grounding pads on the board can be located so that the tabs bear against the pads when the first and second members are secured together to provide an electrical connection between the grounding pads and the metallic housing. Thus, additional fasteners are not needed to secure and ground the board to the housing.

### CROSS REFERENCE TO RELATED APPLICATION

This application claims the benefit of priority under 35 U.S.C. 119(e) to the filing date of Axelrod, U.S. provisional patent application No. 60/486,504 entitled “Enclosure for Cable Modem”, which was filed Jul. 11, 2003, and is incorporated herein by reference in its entirety.

### FIELD OF THE INVENTION

The present invention relates generally to broadband communication network devices, and more particularly to metal housings thereof that have minimal construction steps and that provide reliable grounding points.

### BACKGROUND

Community antenna television (“CATV”) networks have been used for more then four decades to deliver television programming to a large number of subscribers. Increasingly, CATV networks are used by providers to provide data services to subscribers. For example, cable modems used in a broadband cable modem termination system (“CMTS”) compete with digital subscriber lines (“DSL”) and DSL modems used therein, which are typically implemented and supported by telephone companies.

Like many typical consumer electronic devices, cable modems typically comprise a housing made of plastic, internal circuitry on a board that is fastened to the housing with fasteners, such as screws and connectors mounted rigidly mounted to the housing for transmitting communication signals and receiving external electrical power. To facilitate RF shielding, the plastic housing usually must have metallic sections fashioned around the circuitry portions where such energy can radiate.

While the typical housing may function well enough, the fasteners and extra shielding add to the cost of manufacturing over the cost of just the plastic housing parts, which typically comprise two halves that join together to form the enclosure. Not only does each part have a material cost associated with it, the labor cost to assemble the fasteners and shield and housing halves also adds to the cost of the device, whether it is assembled by humans or by an expensive automatic machine.

Thus, there is a need for a device housing that secures internal circuitry and provides shielding of RF frequencies that is simple to assemble.

### BRIEF DESCRIPTION OF THE DRAWINGS

FIG. 1 illustrates a housing for enclosing electronic circuitry.

FIG. A-A illustrates a cross section of a cam-tab that secures first and second members of an electronic circuitry housing together.

FIG. 2 illustrates a housing for enclosing electronic circuitry having a cam-tab with a flat elongate edge.

FIG. B-B illustrates a cross section of a cam-tab that has a flat elongate edge.

FIG. 3 illustrates a housing for enclosing electronic circuitry with a circuit board retained by a cam-tab.

FIG. C-C illustrates a cross section of a cam-tab that secures first and second members of an electronic circuitry housing together, as well as a circuit board against a support pad.

FIG. 4 illustrates a housing for enclosing electronic circuitry with a circuit board retained by a cam-tab that contacts a grounding pad of the board.

FIG. D-D illustrates a cross section of the relationship of the cam-tab securing first and second members of an electronic circuitry housing together, as well as a circuit board, against a support pad with the cam-tab contacting a grounding pad.

### DETAILED DESCRIPTION

As a preliminary matter, it will be readily understood by those persons skilled in the art that the present invention is susceptible of broad utility and application. Many methods, embodiments and adaptations of the present invention other than those herein described, as well as many variations, modifications, and equivalent arrangements, will be apparent from or reasonably suggested by the present invention and the following description thereof, without departing from the substance or scope of the present invention.

Accordingly, while the present invention has been described herein in detail in relation to preferred embodiments, it is to be understood that this disclosure is only illustrative and exemplary of the present invention and is made merely for the purposes of providing a full and enabling disclosure of the invention. This disclosure is not intended nor is to be construed to limit the present invention or otherwise to exclude other embodiments, adaptations, variations, modifications and equivalent arrangements, the present invention being limited only by the claims appended hereto and the equivalents thereof.

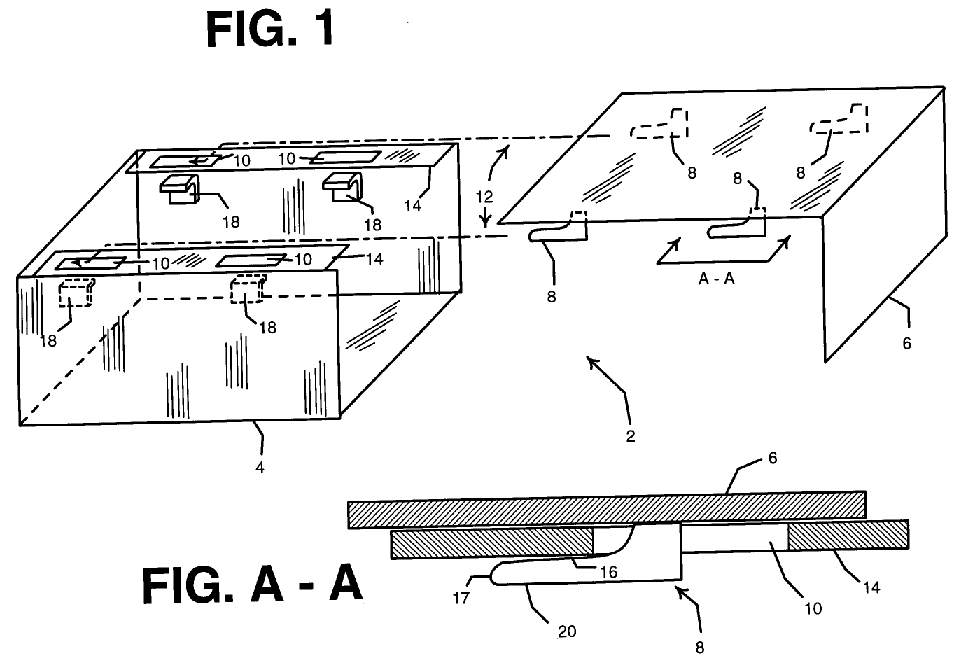

Turning now to the figures, FIG. 1 illustrates a housing 2 for enclosing electronic circuitry and preventing electromagnetic interference (“EMI”) from radiating therefrom. A first member 4 and a second member 6 are preferable manufactured from a metallic material, such as, for instance, sheet steel, to prevent the escape of EMI radiation.

To secure first member 4 and second member 6 together, attachment cam-tabs 8 fit into attachment slots 10, which are defined in first member 4. When second member 6 is mated with first member 4 such that tabs 8 fit into slots 10, the second member can slide according to movement arrows 12 to engage attachment cam-tabs 8 against the underside of locating rails 14, which is preferably defined by first member 4. This sliding engagement is facilitated by the tapered elongate edges 16 of cam-tabs 8.

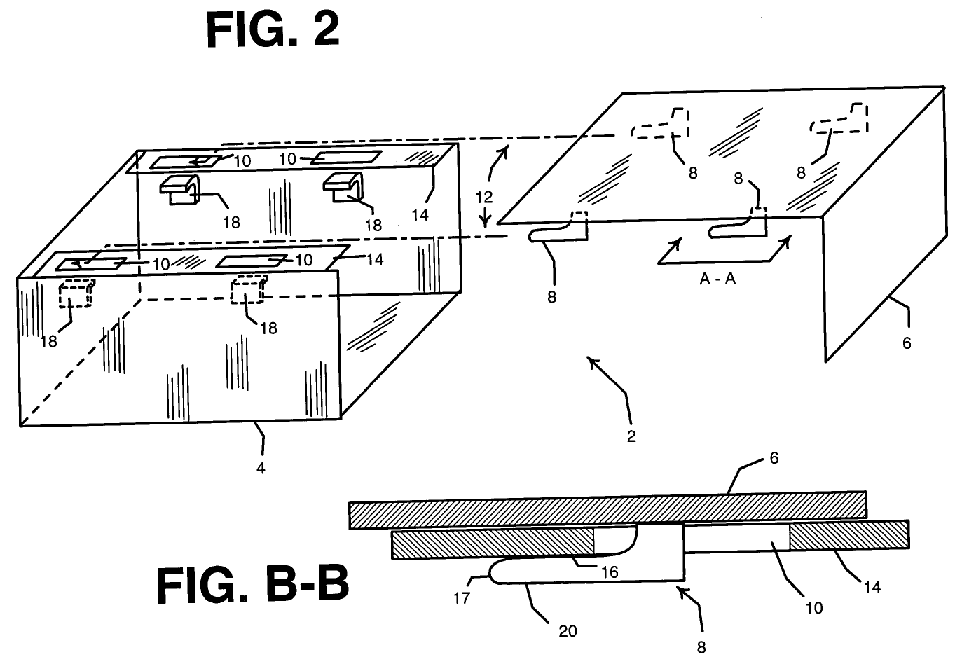

Figure A-A shows a cross sectional view of cam-tab 8 mounted to second member 6. The view shows second member 6 secured to rail 14 of the first member after cam-tab 8 has been inserted into hole 10 and the second member (as well as the attached cam-tab) has been slid to the left with respect to the first member. After rounded leading edge 17 has guided tab 8 under rail 14, the taper of elongate edge 16 causes second member 6 to be pulled toward rail 14. However, it will be appreciated that in another embodiment, elongate edge 16 may be flat and parallel to rail 14, such that leading edge 17 is what produces the cam function of providing a rounded initial contact edge to guide the movement of tab 8 as it moves leftward with respect to rail 14. Thus, the flat/parallel edge of this other embodiment would spread the force that clamps second member 6 to rail 14 of first member 4 over a greater area, or edge-length. An embodiment having a flat elongate edge 16 is shown in FIGS. 2 and B-B.

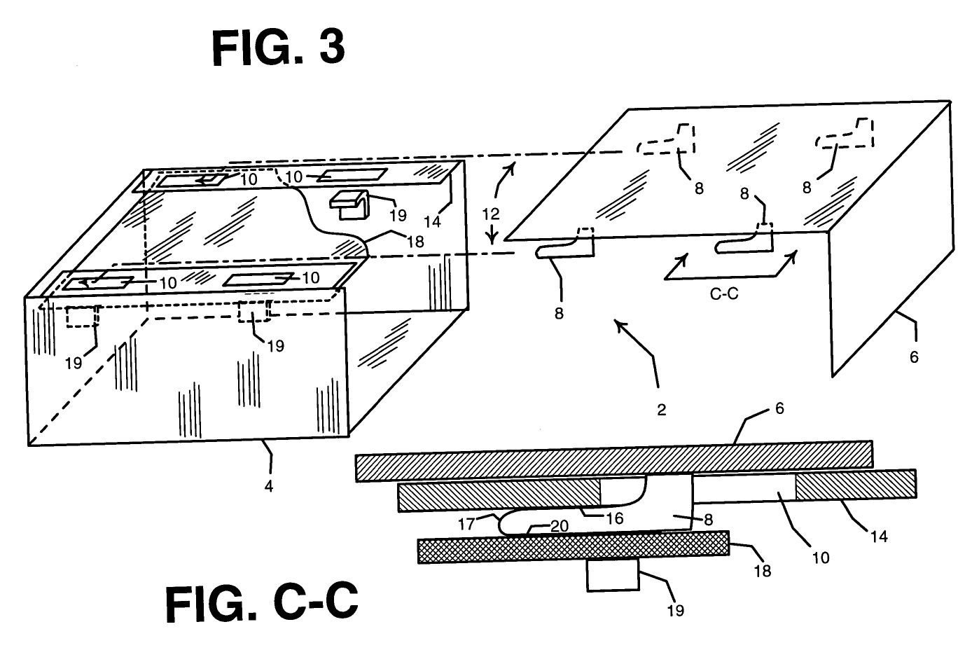

The first member 4 may be more securely retained to the second member 6 if a circuit board 18, or similar means known in the art for providing a foundation for circuitry components, is installed against support pads 19, as shown in FIG. 3. When circuit board 18 is installed against support pads 19, the sliding engagement causes the bearing edge 20 of cam-tab 8 to increasingly bear against the edge of the circuit board as second member 6 slides left with respect to first member 4 when tabs 8 have been inserted through slots 10 and under rails 14.

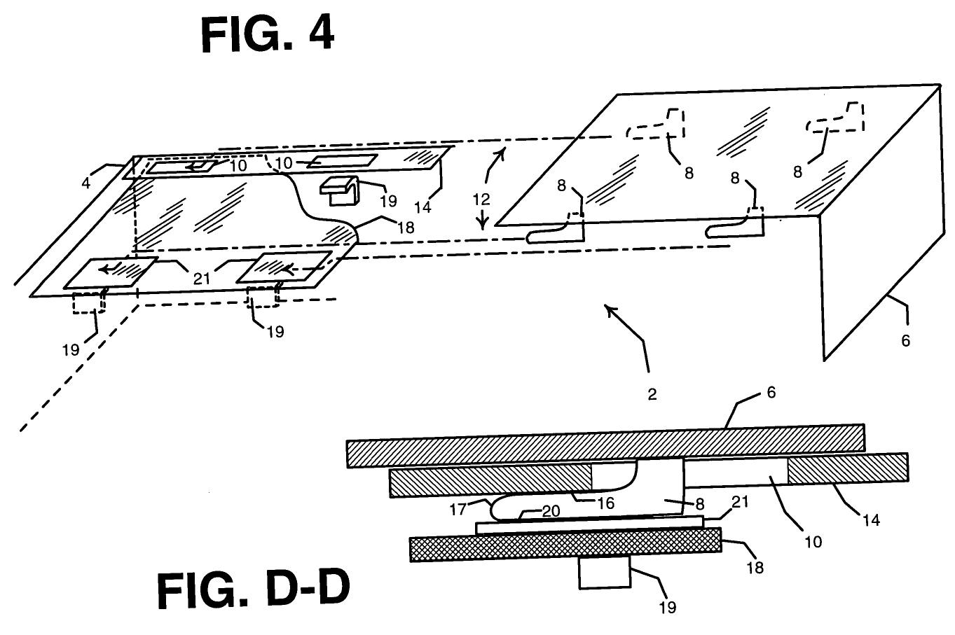

As shown in FIGS. 4 and D-D, further advantage is provided if the engagement area of the circuit board 18 that contacts the bearing edge 20 of cam-tab 8 is configured as a grounding pad 21, known in the art. Thus, a grounding pad 21 may be located at the contact point of the bearing edge 20 of each cam-tab 8 such that circuit board's 18 ground buss/trace is grounded to the metallic housing 2. It will be appreciated that grounding pads 21 on board 18 can be located to contact either the bearing edges 20 of cam-tabs 8, or support tabs 19, or both, as both are preferably metallic and electrically coupled to either second member 6 or first member 4 respectively. The contact area of circuit board 18 may be discrete pads precisely located to engage bearing edges 20 when cam-tabs 8 secured second member 6 to first member 4. Alternatively, ground pads may be formed such that they form one or more continuous traces proximate the perimeter of the trace, at least near the edges of board 18 that are parallel to locating rails 14. This provides flexibility in the locating of cam-tabs 8 on second member 6 and flexibility in the defining of attachment slots 10 in locating rails 14.

These and many other objects and advantages will be readily apparent to one skilled in the art from the foregoing specification when read in conjunction with the appended drawings. It is to be understood that the embodiments herein illustrated are examples only, and that the scope of the invention is to be defined solely by the claims when accorded a full range of equivalents.

1. A housing for electronic circuitry comprising:
a first metallic member having a plurality of attachment cam-tabs, each cam-tab having a bearing edge and an elongate edge; and
a second metallic member having attachment slots for receiving the attachment cam-tabs of the first member such that sliding engagement secures one member to the other.

2. The housing of claim 1 further comprising at least one locating rail defined by the first member, the locating rail defining the attachment slots such that sliding engagement of the elongate edge and the locating rails secures said first and second metallic members together.

3. The housing of claim 1 wherein one of the members further comprises support pads for locating circuitry within the housing.

4. The housing of claim 1 wherein the bearing edge of at least one of the cam-tabs contacts a grounding pad of a circuit board enclosed by the housing when sliding engagement of the first member with respect to the second member has secured said members together such that the circuit board is grounded through the cam-tab to the housing and the circuit board is secured within the housing.

5. The housing of claim 1 wherein the cam-tab further comprises a rounded leading edge and wherein the elongate edge is parallel to the direction of sliding engagement.
